(19) United States
(12) Patent Application Publication
(10) Pub. No.: US 2008/0259574 A1
(43) Pub. Date: Oct. 23, 2008

(54) SLIDE-SPRING MECHANISM FOR PORTABLE DEVICE

(75) Inventor: Henning TASCHKE, Bochum (DE)

Correspondence Address: K.F. ROSS P.C., 5683 RIVERDALE AVENUE, SUITE 203 BOX 900, BRONX, NY, 10471-0900, US

(73) Assignee: LUMBERG CONNECT GmbH

(21) Appl. No.: 12/103,507

(22) Filed: Apr. 15, 2008

(30) Foreign Application Priority Data
Apr. 18, 2007 (DE) 102007018179.7

(51) Int. Cl. H05K 7/16; H05K 5/03

(52) U.S. Cl. 361/727

(57) ABSTRACT

A portable device has a pair of parts shiftable relative to each other between two offset end positions and connected together by a spring mechanism having the invention respective pivots on the parts and a C-shaped spring having opposite ends. One of the ends is secured to one of the pivots, and the other of the spring ends is directly or indirectly connected to the other pivot such that the spring is pivoted about the one pivot on movement of the parts between the end positions and is more tensioned as the parts move through a metastable position between the end positions than when the parts are in the end positions.

### FIELD OF THE INVENTION

The present invention relates to a portable device. More particularly this invention concerns a slide-spring mechanism for controlling two relatively shiftable parts of such a device.

### BACKGROUND OF THE INVENTION

A standard portable device, such as a cell phone, a portable computer, or a personal digital assistant (PDA), has at least two housing parts that are movable relative to each other, and at least one spring having two pivots each carried on a respective one of the housing parts. When the two parts are moved between from one end position to another, normally in a straight line but possibly in an arc with pivoting action, the spring is tensioned until a metastable point generally in the middle of the travel is reached. At this point spring tension is at a maximum and movement past this point is effected automatically by release of this tension, pushing the parts into the other end position. This metastable or toggle action is effective in both directions and serves not only to ease opening and closing of the device, but also to hold it in its end positions.

Such a device is described in U.S. Pat. No. 6,822,871 in the form of a cell phone, whose upper and lower housing cases slide relative against each other. Integral parts of this slide are two torque or leg springs having spring coils arranged across from each other between the parts, with the end of one leg of each spring pivoted on one of the parts and the other leg pivoted on the other part. As the parts move in a travel direction between their end positions the springs pivot through about 90°, with their legs generally parallel to each other in the central metastable position. When using such a mechanism for opening or closing the cell phone housing, recesses must be provided in the slide for pivot of the leg springs, as well as a leg spring cover.

Increasingly high demands are being made of such devices with regard to their miniaturization. The devices are increasingly smaller, while at the same time the number of functions they perform is becoming larger so that a constantly decreasing amount of installation space is available for an increasing number of components. The spring/slide mechanism formed by leg springs of a certain size takes up quite a bit of space within the portable device.

### OBJECTS OF THE INVENTION

It is therefore an object of the present invention to provide an improved slide-spring mechanism for a portable device.

Another object is the provision of such an improved slide-spring mechanism for a portable device that overcomes the above-given disadvantages, in particular that is extremely compact.

A further object is to provide such a device that is scalable, that is that can readily be adapted to relatively long portable devices.

### SUMMARY OF THE INVENTION

A portable device according to the invention has a pair of parts shiftable relative to each other between two offset end positions and connected together by a spring mechanism having respective pivots on the parts and a C-shaped spring having opposite ends. One of the ends is secured to one of the pivots, and the other of the spring ends is directly or indirectly connected to the other pivot such that the spring is pivoted about the one pivot on movement of the parts between the end positions and is more tensioned as the parts move through a metastable position between the end positions than when the parts are in the end positions. In other words when the device is opened or closed the C-shaped spring pivots in a plane parallel to the travel direction of the housing parts on relative movement of the housing parts.

The use of such a C-shaped section, particularly if it is made as a stamped part according to a preferred embodiment, requires a substantially smaller installation space with regard to height, since no spring coils are present that are positioned on top of each other. The entire spring can have the thickness of the sheet of metal or plastic from which it is stamped.

A complicated slide construction can also be omitted since the first and second housing parts have two guides rail assemblies that interfit and stabilize the sliding opening movement, like a tongue-and-groove connection. The movement space of the C-shaped section when opening or closing the housing is substantially smaller.

Particularly preferred is an embodiment in which the spring has multiple C-shaped sections that are connected to each other and are arranged in series between two pivots. The serial arranging next to each other of multiple C-shaped springs enables the influencing of the spring travel and spring tension in an advantageous manner. In this manner, technical demands of the opening mechanism can be transferred easily for opening on one hand, and the requirements of an advantageous operating sensation can be met on the other hand.

It is of particular advantage if the C-shaped sections have different radii and are arranged so that they are nested inside one other, the spring having a smaller radius being essentially positioned within the next larger spring, since a spring is created in this manner that does not require more installation and movement space than an individual C-shaped section, however, and can be easily adjusted with regard to its spring properties, in particular the spring travel and spring tension.

In order to keep the space needed for the spring to move within the device as low as possible, a pivot substantially forms the center point of the spring radii.

The spring travel of a C-shaped section according to the invention can be influenced, particularly extended, in that the first pivot is associated with the first housing part with the interposition of a lever, and is guided in its relative movement toward the second housing part. Even if this design is slightly more complex than the one previously described, it has the substantial advantage that a larger spring travel can be provided to a comparably smaller spring so that in consideration of all parts a smaller installation space is necessary for the mechanism for opening or closing the device.

A concrete embodiment of this lever is characterized in that the lever has a lever bearing or guide that is arranged on the second housing part in a stationary manner, a pivot bearing for the first pivot, and a housing bearing associated with the first housing part, the pivot bearing and the housing bearing enabling movement of the means engaging into the respective bearing along the longitudinal lever axis.

The design can be further simplified if the lever embodies the lever bearing on one hand and is pivotally supported in that position to hold the housing bearing on the other hand, and the pivot bearing the lever bearing and the housing bearing, the housing bearing and the pivot bearing each being preferably embodied as an elongated slot parallel to the longitudinal lever axis.

According to the invention the lever bearing is arranged at the second pivot, since in this case only one bearing element is necessary on the housing side for the pivot and lever, thus simplifying the design further. The pivots are rotatably supported.

### BRIEF DESCRIPTION OF THE DRAWING

The above and other objects, features, and advantages 15 will become more readily apparent from the following description, reference being made to the accompanying drawing in which:

FIG. 1 is an elevational view of the spring according to the invention;

FIGS. 2A, 2B, and 2C are views of the spring of FIG. 1 in one end position, a central metastable position, and another end position, respectively;

FIGS. 3A, 3B, and 3C are views like respective FIGS. 3A, 3B, and 3C showing the spring in a somewhat different installation; and

FIGS. 4A, 4B, and 4C are schematic views of a portable device in one end position, a central metastable position, and another end position in accordance with the invention.

### SPECIFIC DESCRIPTION

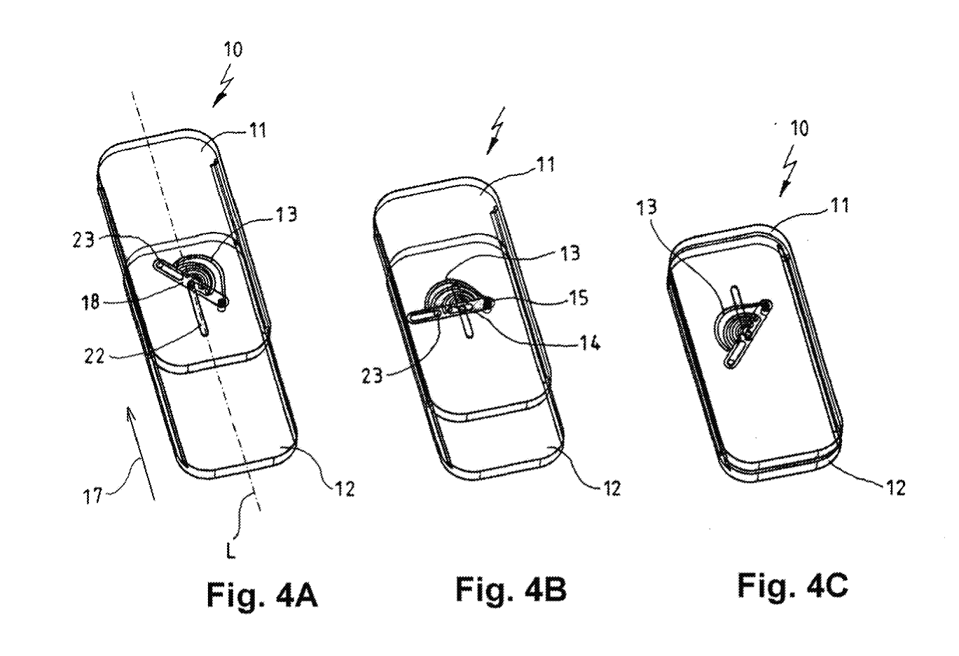

As seen in FIGS. 4A-4C a portable device, in this case a cell phone, 10 has a first housing part—upper case 11—and a second housing part—lower case 12—that can be displaced relative to each other along a longitudinal axis L of the cell phone 10 between one end position shown in FIG. 4A with the two parts 11 and 12 offset from each other and only overlapping somewhat at ends, through a central metastable position shown in FIG. 4B in which they overlay quite a bit more, and an opposite end position shown in FIG. 4C in which they are substantially congruent and aligned.

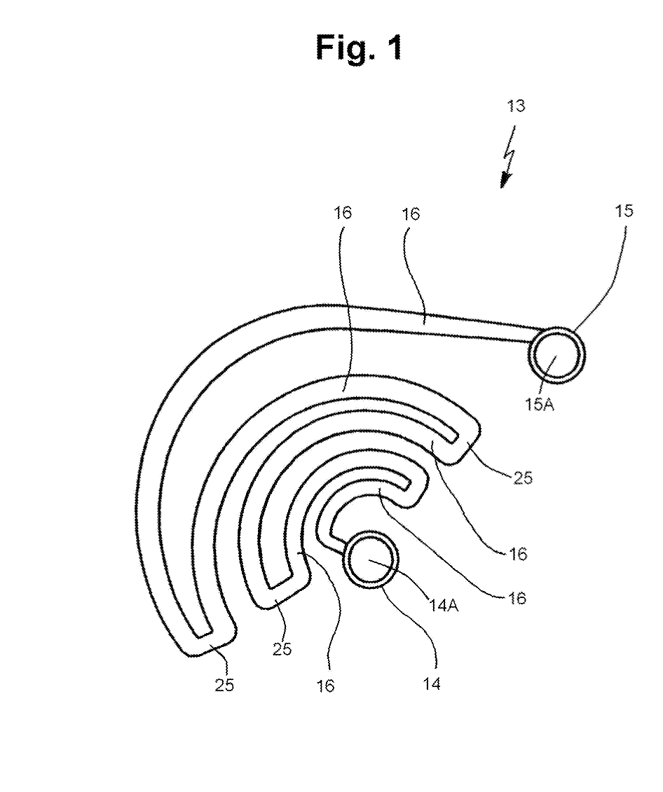

A spring 13 illustrated in detail in FIG. 1 is an integral part of the cell phone 10. In its simplest form the spring is embodied as a simple C-shaped section, which is not illustrated. The spring 13 illustrated in FIG. 1 has a first pivot embodied as an eye 14, and a second pivot embodied as another eye 15 defining respective parallel axes 14A and 15A perpendicular to a plane of the spring 13, which is made of flat sheet metal. Both eyes 14 and 15 serve for the connection of a respective end of the spring 13 to a housing part 11 or 12.

The spring 13 illustrated in FIG. 1 consists of a plurality of generally semicircular and concentric C-shaped sections 16 that are connected to one another at their ends by straight bight regions 25 here extending generally radially of the axis 14A of the eye 14. The sections 16 are interconnected by the bights 25 in a meander. The arrangement of concentric C-shaped sections 16 serves to add together the spring properties of the C-shaped sections 16, with regard to spring tension and the spring travel, which add up to the spring properties of the spring 13.

In the illustrated embodiment the C-shaped sections 16 are arranged so that they are nested inside each other. Each of the C-shaped sections 16 has a different radius, each C-shaped section 16 being arranged within the next larger C-shaped section 16. In this manner, the spring 13 takes up hardly more installation space than the largest C-shaped section 16, so the basic shape of the C-spring can be advantageously be further embodied with regard to its spring properties in an extremely space-saving manner.

The spring 13 with its individual C-shaped sections 16 is made of a single piece of stamped out sheet metal or plastic. Since the C-shaped sections 16 of the spring 13 are nested inside each other, the sections 16 are the equivalent of multiple turns of a standard spring.

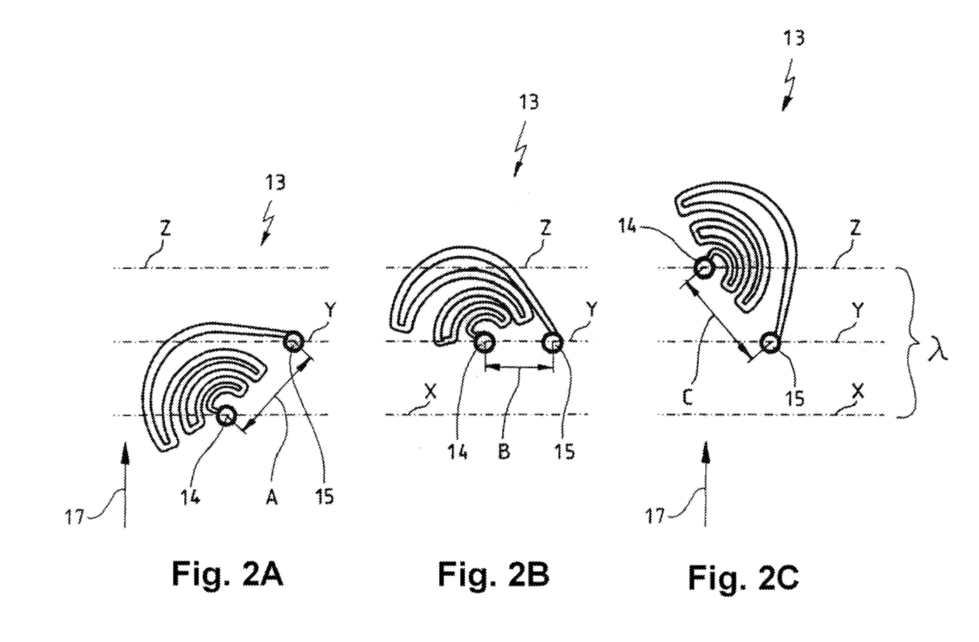

FIGS. 2A-2C show the action of the spring 13 within the device 10. For this purpose the device housing (not illustrated) is positioned in a first end position with regard to the illustration of the spring 13 in FIG. 2A, in a metastable force-reversing position of the spring 13 in FIG. 2B, and in its opposite end position in the illustration of the spring 13 on the right side. The eye 14 is pivoted on the upper case 11 (not illustrated), and the eye 15 is pivoted on the lower case 12 (not illustrated) of the cell phone 10, the eye 15 being considered stationary in FIG. 2. The unillustrated upper case 11 thus glides across the lower case 12.

Relative movement is in the direction of arrow 17 so that the eye 14 is initially moved in a straight line in the direction 17 toward the line Y. This reduces a spacing A between the eyes 14 and 15 to the distance B illustrated in FIG. 4B where the spring 13 is compressed, and a spring tension is at a maximum.

In the FIG. 4B force-reversing or metastable position of the housing parts 11 and 12, the eyes 14 and 15 are oriented on a line perpendicular to the direction 17, as indicated by line Y. As mentioned, in this position the spring tension of the spring 13 is at its maximum. Once the line Y—the metastable position—is passed, the distance between the eyes 14 and 15 increases, thus releasing spring tension. The spring 13 forces the upper case 11 coupled to the eye 14 into the second end position to set a distance C between the eyes 14 and 15 in the illustration of the spring 13 on the right side in FIG. 2. This distance C here is identical to the distance A, but does not have to be so.

In the straight-line movement in the direction 17 of the eye 14 past the eye 15 as illustrated in FIG. 2, the spring 13 itself pivots or rotates about the eye 15 as the center point. The resulting circular path corresponds approximately to a quarter circle. Movement in the direction of arrow 17 makes the rotation clockwise, while opposite movement makes the rotation in counterclockwise direction, both the travel direction 17 of the housing parts 11 and 12. For this purpose the travel can be adjusted as a path extending parallel to the sliding surface, along which the housing parts 11 and 12 move relative to each other. In addition to sliding as shown, pivoting is also possible.

The spring travel corresponds to the travel covered by the eye 14 from its initial position (FIG. 4A) on the line X up to its end position (FIG. 4C) on the line Z, and is generally denoted by A. This travel simultaneously forms the maximum movement path of the housing parts 11 and 12 relative to each other.

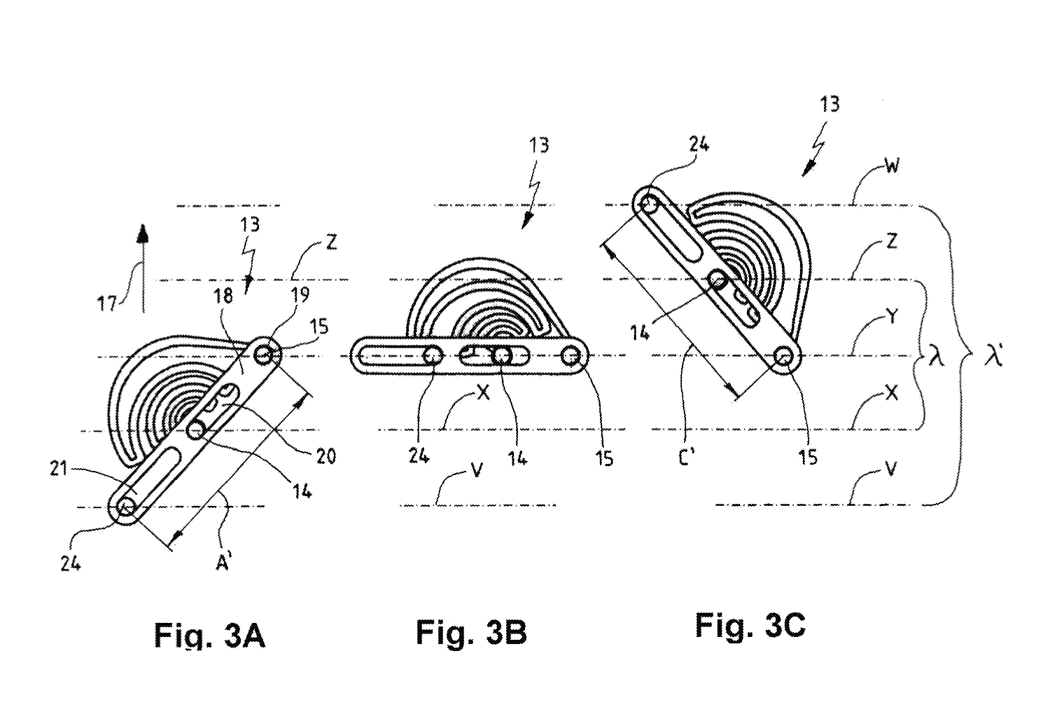

FIGS. 3A to 3C show a further embodiment of the invention. FIGS. 2-2C is laid out like FIG. 3A-3c. Movement of the spring 13 during shifting of the lower case 12 and the upper case 11 is also illustrated in the direction 17. Insofar, the structure of FIGS. 3A-3C is very similar to that of FIGS. 2A-2C.

However, in FIGS. 3A-3C the spring 13 is coupled to a lever 18. The lever 18 is pivoted at one end at 19 with the eye 15 of the spring 13, so that the entire assembly pivots about the axis 15A that is fixed on, for example, the lower case 12. The lever 18 is centrally formed with an elongated guide slot in which the other eye 14 can slide, and at its end opposite the pivot 19 the lever 18 has another longitudinal slot in which can slide a pin 24 projecting from the other part 11 of the device 10. Thus the eye 14 and pin 24 can slide along the respective slots 20 and 21.

During shifting between the end positions as can be seen by a comparison of FIGS. 4A, 4B, and 4C, the eye 14 and pin 24 shift in the slots 20 and 21 from a maximum spacing A′ between the pivots 19 and 24 toward the end pivot 19 until the metastable position of FIG. 3B is reached, in which the pivot 19 (and coaxial eye 15), the eye 14, and the pin 19 are aligned perpendicular to the direction 17. Further movement to the opposite stable end position of FIG. 4C moves the eye 14 and pin 24 away from the pivot 19 in the slots 20 and 21 to a maximum spacing C′ between the pivots 19 and 24 equal to the spacing A′. In this manner, the straight-line movement 17 of the housing parts 11, 12 is translated into rotation of the spring 13. During this action the spring 13 is at maximum tension in the central metastable position of FIG. 3B and at minimal tension in the two end positions of FIGS. 3A and 3C.

In FIG. 2 the travel of the housing parts 11, 12 corresponded to the spring travel A, which is limited by the maximum spacing between of the eyes 14 and 15, since the upper case 11 directly engages into the eye 14, and the lower case 12 is directly connected to the eye 15.

By contrast the lever, or the arrangement of the bearing pin 24 inside of the housing bearing 21, which is spaced from the eye 15, determines the maximum travel of the housing parts 11 and 12 to each other in the end position. The upper case 11 carries the pivot 21 that may be at any desired distance from the eye 14.

In the first end position (FIG. 3A) the pin 24 of the upper case 11 engaging into the slot 21 is positioned on the line V. On the other hand, in the FIG. 3C position this pin 24 is positioned in the slot 21 on the line W. The travel between the upper case 11 and the lower case 12 is extended by the spacing between lines V and X, or W and Z, and therefore by the distance between the eye 14 and the pin 24 of the upper case 11 engaging into the housing bearing 21 is now λ′, which is much more than This embodiment makes it possible to utilize a comparatively small spring with a short spring travel for a large travel between the upper and lower cases 11, 12 so that with a larger travel less installation space is required for the spring 13, or for the mechanism for opening or closing. This newly available space can be utilized for other device components. In addition to the lever 18, the embodiment of FIGS. 3A-3C provides a guide (not illustrated) for the eye 14 that is arranged in the travel direction 17, in order to ensure its straight-line movement, and therefore ensure the build up of a spring tension.

FIGS. 4A-4C illustrate the movement of the spring 13 and the lever 19 illustrated in FIGS. 3A-3C again in connection with the upper case 11 and the lower case 12. The cell phone 10 and its housing parts 11 and 12 are in a first end position in an open state of the housing as shown in FIG. 4A. A pin 23 of the upper case 11 engages into the housing bearing slot 21, the eye 14 is engaged in the pivot bearing slot 20 formed by the lever 18. The eye 14 moves in a straight line in the travel direction 17 along the longitudinal axis L of the cell phone 10 in a groove-like guide 22.

FIG. 4B shows the housing parts 11 and 12 in their metastable position. The eyes 14 and 15, and the pin 23 are on a line extending aligned perpendicular to the longitudinal axis L of the cell phone 10. The tension of the spring 13 is at its maximum. Beyond this metastable position, the spring 13 mechanically forces the upper case 11 into the second end position shown in FIG. 4C, the closed position.

In summary the invention discloses two housing parts 11 and 12 that are displaceable relative to each other and that can be manually moved from a first end position through a metastable position after which they move automatically into their second end position due to the tension built up in the spring 13. For this purpose, only a very small installation place is taken up because of the C-shaped structure of spring 13, which in particular is embodied as a stamped part so that the newly available installation space may be utilized for other assemblies or components.

In a second embodiment the spring travel available is extended by means of a lever 18 such that substantially larger relative movements are possible between the housing parts 11 and 12 with the same spring 13. This spring 13 also contributes to optimizing the volume of the cell phone.

I claim:

1. In a portable device having a pair of parts shiftable relative to each other between two offset end positions, a spring mechanism comprising:
respective pivots on the parts;
a C-shaped spring having opposite ends, one of the ends being secured to one of the pivots; and
means securing the other of the spring ends to the other pivot such that the spring is pivoted about the one pivot on movement of the parts between the end positions and is more tensioned as the parts move through a metastable position between 11 the end positions than when the parts are in the end positions.

2. The mechanism defined in claim 1 wherein the spring has a plurality of C-shaped sections connected in series.

3. The mechanism defined in claim 2 wherein the sections have different radii of curvature and are nested in one another with sections of smaller radius of curvature being received in sections of larger radius of curvature.

4. The mechanism defined in claim 3 wherein the spring has bights interconnecting the sections.

5. The mechanism defined in claim 4 wherein the sections are generally part circular and have centers of curvature that are generally concentric.

6. The mechanism defined in claim 5 wherein the sections are generally semicircular and the bights are straight and extend generally radially from the concentric centers.

7. The mechanism defined in claim 1 wherein the other end of the spring is connected directly on the other pivot.

8. The mechanism defined in claim 7 wherein the spring has a center of curvature generally at the other pivot.

9. The mechanism defined in claim 1 wherein the means is a lever pivoted on the other pivot, the other end of the spring being pivoted on the lever between the pivots.

10. The mechanism defined in claim 9 wherein the parts move relative to each other in a straight line defining a travel direction, the lever being formed with an elongated end guide receiving the other pivot and an elongated center guide receiving the other end of the spring.

11. The mechanism defined in claim 10 wherein the guides are slots extending longitudinally of the lever between the pivots.

12. The mechanism defined in claim 10 wherein in the metastable position the lever extends generally perpendicular to the direction.

13. The mechanism defined in claim 9 wherein the parts move relative to each other in a straight line defining a travel direction, the lever being formed with an end guide receiving the other pivot, one of the housing parts being formed with a guide extending in the direction and receiving the other spring end.

14. The mechanism defined in claim 13 wherein the end guides is a slot extending longitudinally of the lever between the pivots.

15. The mechanism defined in claim 10 wherein the spring is made of sheet metal or plastic and lies in a plane parallel to the direction.

16. The mechanism defined in claim 1 wherein the spring is made of sheet metal or plastic.
